(19) United States
(12) Patent Application Publication
(10) Pub. No.: US 2023/0299206 A1
(43) Pub. Date: Sep. 21, 2023

(54) SEMICONDUCTOR DEVICE AND SEMICONDUCTOR STORAGE DEVICE

(71) Applicant: Kioxia Corporation, Tokyo (JP)

(72) Inventors: Keiko SAKUMA, Yokkaichi Mie (JP); Taro SHIOKAWA, Nagoya Aichi (JP); Kiwamu SAKUMA, Yokkaichi Mie (JP)

(73) Assignee: Kioxia Corporation, Tokyo (JP)

(21) Appl. No.: 17/899,909

(22) Filed: Aug. 31, 2022

(30) Foreign Application Priority Data
Mar. 16, 2022 (JP) 2022-041799

(51) Int. Cl. H01L 29/786; H01L 27/108

(52) U.S. Cl. CPC H01L 29/7869; H01L 29/78609; H01L 27/10805

(57) ABSTRACT

A semiconductor device includes: a first electrode; a second electrode; a first oxide semiconductor layer provided between the first electrode and the second electrode; a gate electrode around the first oxide semiconductor layer; a second oxide semiconductor layer provided between the gate electrode and the first oxide semiconductor layer, and separated from the first electrode; and a gate insulating layer provided between the gate electrode and the second oxide semiconductor layer.

### CROSS-REFERENCE TO RELATED APPLICATION(S)

This application is based upon and claims the benefit of priority from Japanese Patent Application No. 2022-041799, filed on Mar. 16, 2022, the entire contents of which are incorporated herein by reference.

### FIELD

Embodiments described herein relate generally to a semiconductor device and a semiconductor storage device.

### BACKGROUND

An oxide semiconductor transistor that forms a channel in an oxide semiconductor layer has an excellent characteristic that a channel leakage current during an OFF-operation is extremely small. As a result, for example, a dynamic random-access memory (DRAM) may implement its switching transistor as the oxide semiconductor transistor.

### DESCRIPTION OF THE DRAWINGS

FIG. 1 is a schematic cross-sectional view of a semiconductor device according to a first embodiment.

FIG. 2 is a schematic cross-sectional view of the semiconductor device according to the first embodiment.

FIG. 3 is a schematic cross-sectional view of the semiconductor device according to the first embodiment.

FIG. 4 is a schematic cross-sectional view illustrating an example of a method for manufacturing the semiconductor device according to the first embodiment.

FIG. 5 is a schematic cross-sectional view illustrating an example of a method for manufacturing the semiconductor device according to the first embodiment.

FIG. 6 is a schematic cross-sectional view illustrating the example of the method for manufacturing the semiconductor device according to the first embodiment.

FIG. 7 is a schematic cross-sectional view illustrating the example of the method for manufacturing the semiconductor device according to the first embodiment.

FIG. 8 is a schematic cross-sectional view illustrating the example of the method for manufacturing the semiconductor device according to the first embodiment.

FIG. 9 is a schematic cross-sectional view illustrating an example of a method for manufacturing the semiconductor device according to the first embodiment.

FIG. 10 is a schematic cross-sectional view illustrating the example of the method for manufacturing the semiconductor device according to the first embodiment.

FIG. 11 is a schematic cross-sectional view illustrating the example of the method for manufacturing the semiconductor device according to the first embodiment.

FIG. 12 is a schematic cross-sectional view of a semiconductor device according to a comparative example.

FIG. 13 is a schematic cross-sectional view illustrating an example of a method for manufacturing the semiconductor device according to the comparative example.

FIG. 14 is a schematic cross-sectional view illustrating the example of the method for manufacturing the semiconductor device according to the comparative example.

FIG. 15 is a schematic cross-sectional view illustrating the example of the method for manufacturing the semiconductor device according to the comparative example.

FIG. 16 is a schematic cross-sectional view of a semiconductor device according to a second embodiment.

FIG. 17 is a schematic cross-sectional view of a semiconductor device according to Modification of the second embodiment.

FIG. 18 is a schematic cross-sectional view of a semiconductor device according to a third embodiment.

FIG. 19 is a schematic cross-sectional view of a semiconductor device according to a fourth embodiment.

FIG. 20 is an equivalent circuit diagram of a semiconductor storage device according to a fifth embodiment.

FIG. 21 is a schematic cross-sectional view of the semiconductor storage device according to the fifth embodiment.

### DETAILED DESCRIPTION

Embodiments provide a semiconductor device having an excellent transistor characteristic.

In general, according to one embodiment, a semiconductor device includes: a first electrode; a second electrode; a first oxide semiconductor layer provided between the first electrode and the second electrode; a gate electrode around the first oxide semiconductor layer; a second oxide semiconductor layer provided between the gate electrode and the first oxide semiconductor layer, and separated from the first electrode; and a gate insulating layer provided between the gate electrode and the second oxide semiconductor layer.

Hereinafter, embodiments of the present disclosure will be described with reference to drawings. In the following description, the same or similar members may be designated by the same reference numerals, and the description of the members or the like once described may be appropriately omitted.

Further, in the specification, terms “upper” or “lower” may be used for convenience. The terms such as “upper” or “lower” indicate a relative positional relationship in the drawing, and do not define the positional relationship with respect to gravity.

Qualitative analysis and quantitative analysis of a chemical composition of members that constitute a semiconductor device and a semiconductor storage device in the present specification may be performed by, for example, a secondary ion mass spectrometry (SIMS), an energy dispersive X-ray spectroscopy (EDX), and a Rutherford back-scattering spectroscopy (RBS). Further, for example, a transmission electron microscope (TEM) may be used to measure, for example, a thickness of the members that constitute the semiconductor device and the semiconductor storage device, a distance between the members, and a diameter of a crystal grain size.

### First Embodiment

A semiconductor device according to a first embodiment includes: a first electrode; a second electrode; a first oxide semiconductor layer provided between the first electrode and the second electrode; a gate electrode facing the first oxide semiconductor layer; a second oxide semiconductor layer provided between the gate electrode and the first oxide semiconductor layer, and separated from the first electrode; and a gate insulating layer provided between the gate electrode and the second oxide semiconductor layer.

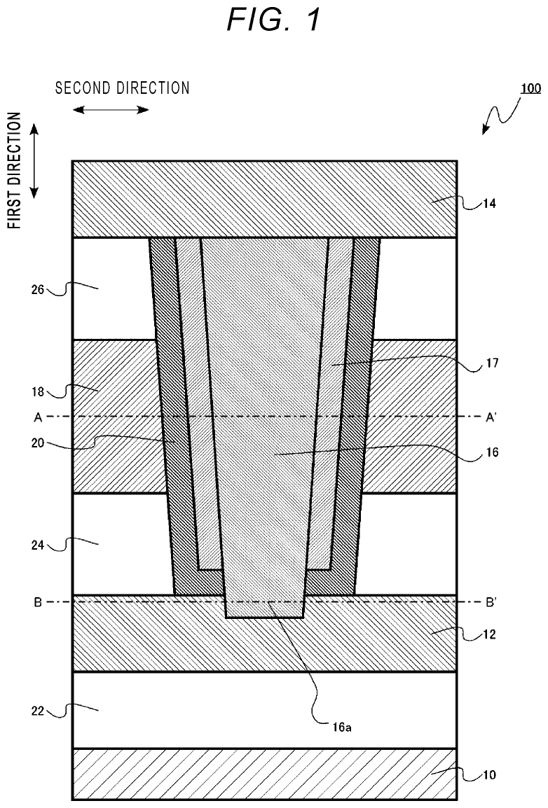

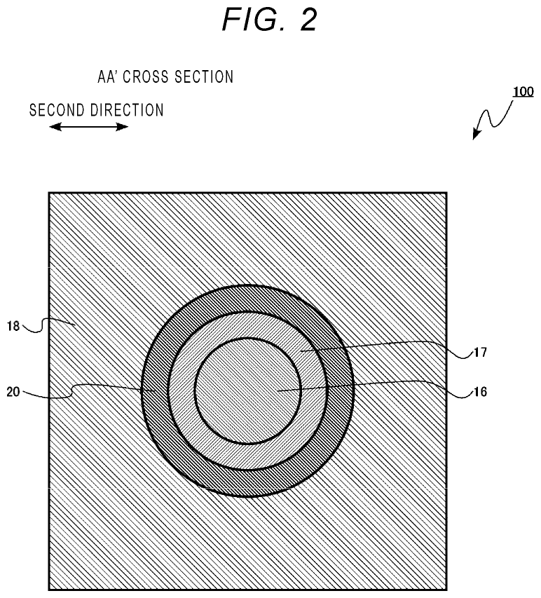

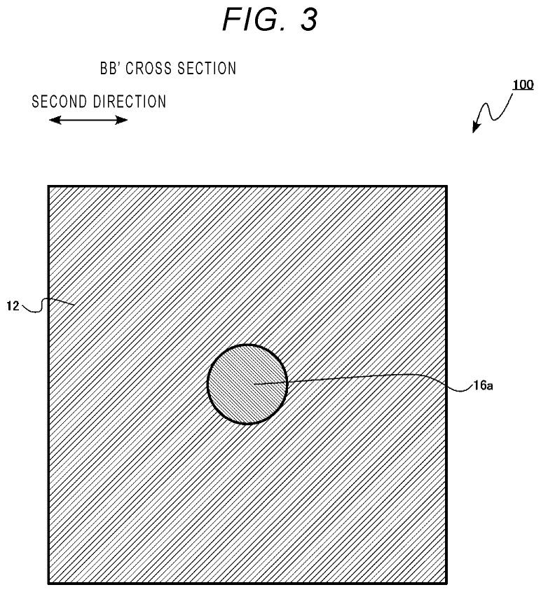

FIGS. 1 to 3 are schematic cross-sectional views of the semiconductor device according to the first embodiment. FIG. 2 is a cross-sectional view taken along line AA′in FIG. 1. FIG. 3 is a cross-sectional view taken along line BB′in FIG. 1. In FIG. 1, the vertical direction is referred to as a first direction. In FIG. 1, the left-right direction is referred to as a second direction. The second direction is perpendicular to the first direction.

The semiconductor device according to the first embodiment is a transistor 100. The transistor 100 is an oxide semiconductor transistor in which a channel is formed in the oxide semiconductor. In the transistor 100, a gate electrode surrounds the oxide semiconductor layer in which the channel is formed. The transistor 100 is a so-called surrounding gate transistor (SGT). The transistor 100 is a so-called vertical transistor.

The transistor 100 is provided with a lower electrode 12, an upper electrode 14, a first oxide semiconductor layer 16, a second oxide semiconductor layer 17, a gate electrode 18, a gate insulating layer 20, a lower insulating layer 24, and an upper insulating layer 26. The first oxide semiconductor layer 16 includes a first portion 16a.

The lower electrode 12 is an example of a first electrode. The upper electrode 14 is an example of a second electrode.

A silicon substrate 10 is made of, for example, single crystal silicon. The substrate is not limited to the silicon substrate. The substrate may be, for example, a semiconductor substrate other than the silicon substrate. The substrate may be, for example, an insulating substrate.

The lower electrode 12 is provided on the silicon substrate 10. A substrate insulating layer 22 is provided between the silicon substrate 10 and the lower electrode 12.

The lower electrode 12 functions as a source electrode or a drain electrode of the transistor 100.

The lower electrode 12 is a conductor. The lower electrode 12 contains, for example, an oxide conductor or a metal. The lower electrode 12 is, for example, an oxide conductor containing indium (In), tin (Sn), and oxygen (O). The lower electrode 12 is, for example, indium tin oxide. The lower electrode 12 is, for example, a metal containing tungsten (W), molybdenum (Mo), copper (Cu), aluminum (Al), titanium (Ti), or tantalum (Ta).

The lower electrode 12 may have, for example, a stacked structure of a plurality of conductors.

The upper electrode 14 is provided on the silicon substrate 10. The upper electrode 14 is provided on the lower electrode 12. A lower electrode 12 is provided between the silicon substrate 10 and the upper electrode 14. The direction directed from the lower electrode 12 to the upper electrode 14 is the first direction.

The upper electrode 14 functions as the source electrode or the drain electrode of the transistor 100.

The upper electrode 14 is a conductor. The upper electrode 14 contains, for example, an oxide conductor or a metal. The upper electrode 14 is, for example, an oxide conductor containing indium (In), tin (Sn), and oxygen (O). The upper electrode 14 is, for example, indium tin oxide. The upper electrode 14 is, for example, a metal containing tungsten (W), molybdenum (Mo), copper (Cu), aluminum (Al), titanium (Ti), or tantalum (Ta).

The upper electrode 14 may have, for example, a stacked structure of a plurality of conductors.

The lower electrode 12 and the upper electrode 14 are made of, for example, the same material. The lower electrode 12 and the upper electrode 14 are, for example, oxide conductors containing indium (In), tin (Sn), and oxygen (O). The lower electrode 12 and the upper electrode 14 are, for example, indium tin oxide.

The first oxide semiconductor layer 16 is provided on the silicon substrate 10. The first oxide semiconductor layer 16 is provided between the lower electrode 12 and the upper electrode 14. The first oxide semiconductor layer 16 is in contact with, for example, the lower electrode 12. The first oxide semiconductor layer 16 is in contact with, for example, the upper electrode 14.

In the cross section perpendicular to the first direction, the width of the first oxide semiconductor layer 16 in the second direction is, for example, decreased from the upper electrode 14 toward the lower electrode 12. For example, in the cross section parallel to the first direction, the side surface of the first oxide semiconductor layer 16 has a forward-taper shape.

The length of the first oxide semiconductor layer 16 in the first direction is, for example, 80 nm or more and 200 nm or less. The width of the first oxide semiconductor layer 16 in the second direction is, for example, 20 nm or more and 100 nm or less.

The first oxide semiconductor layer 16 is an oxide semiconductor. The first oxide semiconductor layer 16 is, for example, amorphous.

The first oxide semiconductor layer 16 contains, for example, at least one element selected from a group consisting of indium (In), gallium (Ga), silicon (Si), aluminum (Al), and tin (Sn), zinc (Zn), and oxygen (O). The first oxide semiconductor layer 16 contains, for example, indium (In), gallium (Ga), and zinc (Zn). The first oxide semiconductor layer 16 contains, for example, indium (In), aluminum (Al), and zinc (Zn).

The first oxide semiconductor layer 16 contains, for example, at least one element selected from a group consisting of titanium (Ti), zinc (Zn), and tungsten (W). The first oxide semiconductor layer 16 contains, for example, titanium oxide, zinc oxide, or tungsten oxide.

The first oxide semiconductor layer 16 has a chemical composition, for example, different from a chemical composition of the lower electrode 12 and a chemical composition of the upper electrode 14.

The first oxide semiconductor layer 16 includes the first portion 16a. As illustrated in FIG. 3, the first portion 16a is surrounded by the lower electrode 12 in the plane perpendicular to the first direction.

The first oxide semiconductor layer 16 includes, for example, an oxygen vacancy. The oxygen vacancy in the first oxide semiconductor layer 16 functions as a donor.

The second oxide semiconductor layer 17 is provided on the silicon substrate 10. The second oxide semiconductor layer 17 is provided between the gate electrode 18 and the first oxide semiconductor layer 16.

As illustrated in FIG. 2, the second oxide semiconductor layer 17 surrounds the first oxide semiconductor layer 16. The second oxide semiconductor layer 17 is in contact with the first oxide semiconductor layer 16.

The second oxide semiconductor layer 17 is provided between the lower electrode 12 and the upper electrode 14. The second oxide semiconductor layer 17 is separated from the lower electrode 12. The second oxide semiconductor layer 17 is separated from the lower electrode 12 in the first direction. In the first direction, the gate insulating layer 20 is provided between the second oxide semiconductor layer 17 and the lower electrode 12.

For example, in the cross section parallel to the first direction, the side surface of the second oxide semiconductor layer 17 has a forward-taper shape.

When the transistor 100 is turned on, a channel serving as a current path is formed in the second oxide semiconductor layer 17.

The second oxide semiconductor layer 17 is an oxide semiconductor. The second oxide semiconductor layer 17 is, for example, amorphous.

The second oxide semiconductor layer 17 contains, for example, at least one element selected from a group consisting of indium (In), gallium (Ga), silicon (Si), aluminum (Al), and tin (Sn), zinc (Zn), and oxygen (O). The second oxide semiconductor layer 17 contains, for example, indium (In), gallium (Ga), and zinc (Zn). The second oxide semiconductor layer 17 contains, for example, indium (In), aluminum (Al), and zinc (Zn).

The second oxide semiconductor layer 17 contains, for example, at least one element selected from a group consisting of titanium (Ti), zinc (Zn), and tungsten (W). The second oxide semiconductor layer 17 contains, for example, titanium oxide, zinc oxide, or tungsten oxide.

The second oxide semiconductor layer 17 has, for example, the same chemical composition as the first oxide semiconductor layer 16. The second oxide semiconductor layer 17 has a chemical composition, for example, different from the chemical composition of the lower electrode 12 and the chemical composition of the upper electrode 14.

In the second oxide semiconductor layer 17, the thickness of the portion between the gate insulating layer 20 and the first oxide semiconductor layer 16 is, for example, 2 nm or more and 10 nm or less.

The gate electrode 18 faces the first oxide semiconductor layer 16. Further, the gate electrode 18 faces the second oxide semiconductor layer 17. The gate electrode 18 is provided such that the position coordinate in the first direction has a value between the position coordinate of the lower electrode 12 in the first direction and the position coordinate of the upper electrode 14 in the first direction.

As illustrated in FIG. 2, the gate electrode 18 surrounds the first oxide semiconductor layer 16. The gate electrode 18 is provided around the first oxide semiconductor layer 16.

As illustrated in FIG. 2, the gate electrode 18 surrounds the second oxide semiconductor layer 17. The gate electrode 18 is provided around the second oxide semiconductor layer 17.

The gate electrode 18 is, for example, a metal, a metal compound, or a semiconductor. The gate electrode 18 contains, for example, tungsten W.

The length of the gate electrode 18 in the first direction is, for example, 20 nm or more and 100 nm or less.

The gate insulating layer 20 is provided between the gate electrode 18 and the second oxide semiconductor layer 17. The gate insulating layer 20 surrounds the second oxide semiconductor layer 17. The gate insulating layer 20 is in contact with the second oxide semiconductor layer 17.

The gate insulating layer 20 is, for example, an oxide, a nitride, or an oxynitride. The gate insulating layer 20 contains, for example, silicon oxide, silicon nitride, silicon oxynitride, aluminum oxide, hafnium oxide, or zirconium oxide. The gate insulating layer 20 includes, for example, a silicon oxide film, a silicon nitride film, a silicon oxynitride film, an aluminum oxide film, a hafnium oxide film, or a zirconium oxide film. The gate insulating layer 20 includes, for example, a stacked film of the films listed above. The thickness of the gate insulating layer 20 is, for example, 2 nm or more and 10 nm or less.

The substrate insulating layer 22 is provided between the silicon substrate 10 and the lower electrode 12. The substrate insulating layer 22 is, for example, an oxide, a nitride, or an oxynitride. The substrate insulating layer 22 contains, for example, silicon oxide, silicon nitride, or silicon oxynitride. The substrate insulating layer 22 is, for example, silicon oxide, silicon nitride, or silicon oxynitride.

The lower insulating layer 24 is provided on the lower electrode 12. The lower insulating layer 24 is provided between the gate electrode 18 and the lower electrode 12.

The lower insulating layer 24 surrounds the first oxide semiconductor layer 16 and the second oxide semiconductor layer 17. The lower insulating layer 24 surrounds the gate insulating layer 20. The gate insulating layer 20 is provided between the lower insulating layer 24 and the second oxide semiconductor layer 17.

The lower insulating layer 24 is, for example, an oxide, a nitride, or an oxynitride. The lower insulating layer 24 contains, for example, silicon oxide, silicon nitride, or silicon oxynitride. The lower insulating layer 24 contains, for example, a silicon oxide layer, a silicon nitride layer, or a silicon oxynitride layer. The lower insulating layer 24 is, for example, a silicon oxide layer, a silicon nitride layer, or a silicon oxynitride layer.

The upper insulating layer 26 is provided on the gate electrode 18. The upper insulating layer 26 is provided between the gate electrode 18 and the upper electrode 14.

The upper insulating layer 26 surrounds the first oxide semiconductor layer 16 and the second oxide semiconductor layer 17. The upper insulating layer 26 surrounds the gate insulating layer 20. The gate insulating layer 20 is provided between the upper insulating layer 26 and the second oxide semiconductor layer 17.

The upper insulating layer 26 is, for example, an oxide, a nitride, or an oxynitride. The upper insulating layer 26 contains, for example, silicon oxide, silicon nitride, or silicon oxynitride. The upper insulating layer 26 contains, for example, a silicon oxide layer, a silicon nitride layer, or a silicon oxynitride layer. The upper insulating layer 26 is, for example, a silicon oxide layer, a silicon nitride layer, or a silicon oxynitride layer.

Subsequently, an example of a method for manufacturing the semiconductor device according to the first embodiment will be described.

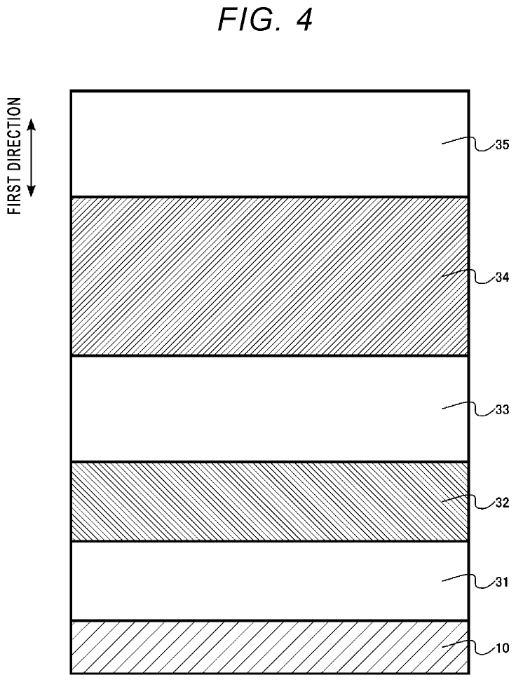

FIGS. 4 to 11 are schematic cross-sectional views illustrating the example of the method for manufacturing the semiconductor device according to the first embodiment. Each of FIGS. 4 to 11 illustrates a cross section corresponding to FIG. 1. FIGS. 4 to 11 are drawings illustrating an example of a method for manufacturing the transistor 100.

First, on the silicon substrate 10, a first silicon oxide film 31, a first indium tin oxide film 32, a second silicon oxide film 33, a tungsten layer 34, and a third silicon oxide film 35 are stacked in the first direction in this order (FIG. 4). The first silicon oxide film 31, the first indium tin oxide film 32, the second silicon oxide film 33, the tungsten layer 34, and the third silicon oxide film 35 are formed by, for example, a chemical vapor deposition method (CVD method).

The first silicon oxide film 31 finally becomes the substrate insulating layer 22. A part of the first indium tin oxide film 32 finally becomes the lower electrode 12. A part of the second silicon oxide film 33 finally becomes the lower insulating layer 24. A part of the tungsten layer 34 finally becomes the gate electrode 18. A part of the third silicon oxide film 35 finally becomes the upper insulating layer 26.

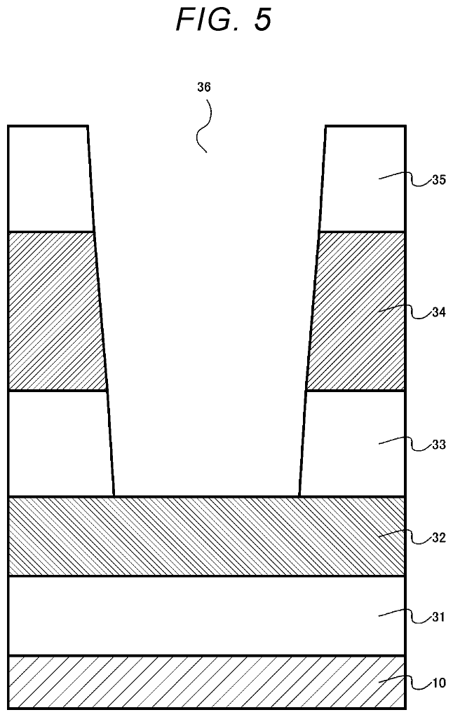

Subsequently, an opening 36 that penetrates the third silicon oxide film 35, the tungsten layer 34, and the second silicon oxide film 33 from the surface of the third silicon oxide film 35, and reaches the first indium tin oxide film 32 is formed (FIG. 5). The opening 36 has, for example, a forward-taper shape in which the diameter of the hole decreases toward the first indium tin oxide film 32. The opening 36 is formed by using, for example, a lithography method and a reactive ion etching method (RIE method).

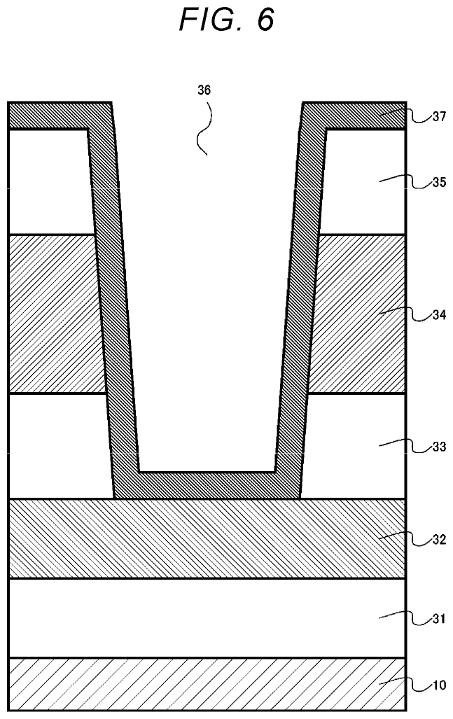

Subsequently, a fourth silicon oxide film 37 is formed inside the opening 36 (FIG. 6). The fourth silicon oxide film 37 is formed by, for example, a CVD method. A part of the fourth silicon oxide film 37 finally becomes the gate insulating layer 20.

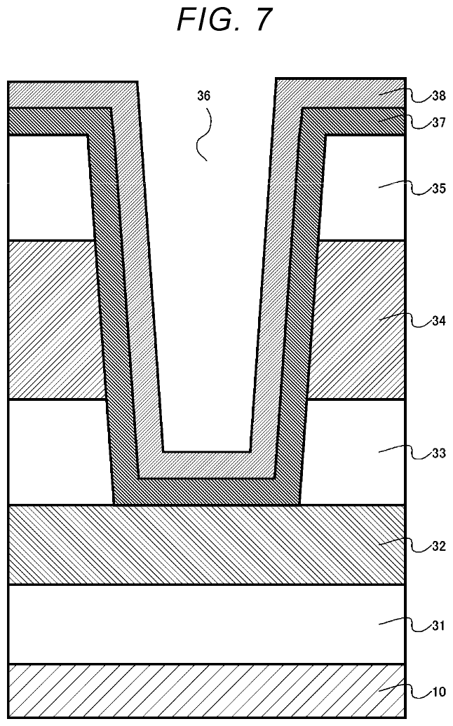

Subsequently, a first oxide semiconductor film 38 is formed inside the opening 36 (FIG. 7). A part of the first oxide semiconductor film 38 becomes the second oxide semiconductor layer 17.

The first oxide semiconductor film 38 contains, for example, indium (In), gallium (Ga), and zinc (Zn). The first oxide semiconductor film 38 is formed by, for example, a CVD method.

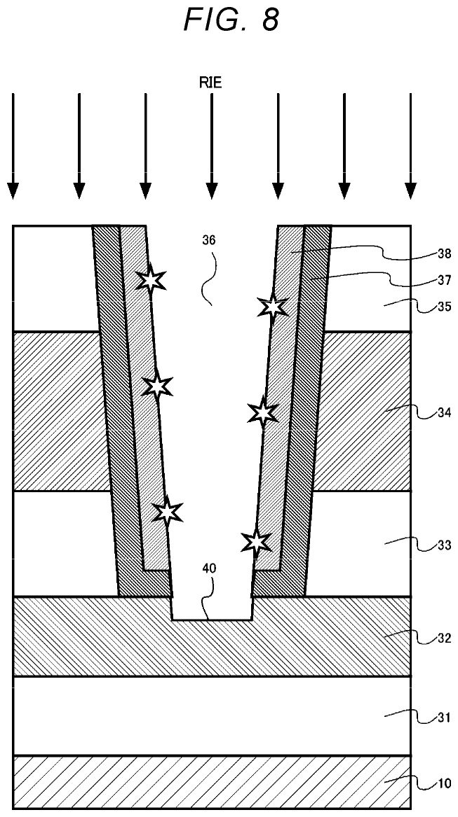

Subsequently, the first oxide semiconductor film 38 and the fourth silicon oxide film 37 at the lower portion of the opening 36 are etched to expose the first indium tin oxide film 32 (FIG. 8). Further, the first indium tin oxide film 32 is etched to form a recess portion 40. The first oxide semiconductor film 38, the fourth silicon oxide film 37, and the first indium tin oxide film 32 are etched by using a RIE method.

When the first oxide semiconductor film 38, the fourth silicon oxide film 37, and the first indium tin oxide film 32 are etched, the surface of the first oxide semiconductor film 38 is exposed to the etching, and thus, processing damage is added.

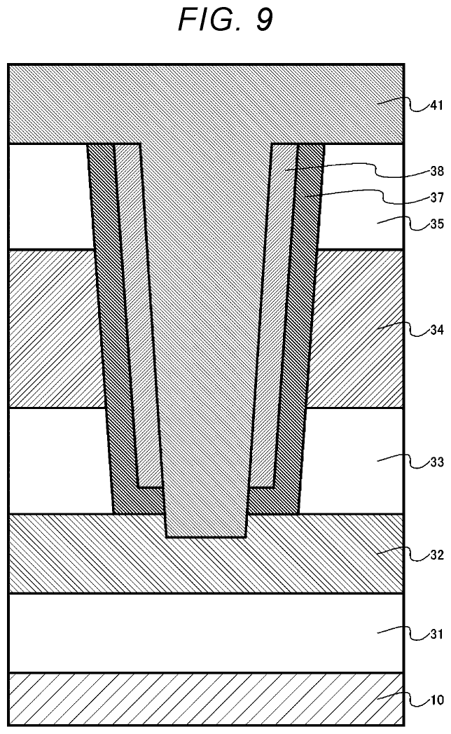

Subsequently, the opening 36 is buried with a second oxide semiconductor film 41 (FIG. 9). A part of the second oxide semiconductor film 41 becomes the first oxide semiconductor layer 16. The first oxide semiconductor layer 16 that buries the recess 40 becomes the first portion 16a of the first oxide semiconductor layer 16.

The second oxide semiconductor film 41 contains, for example, indium (In), gallium (Ga), and zinc (Zn). The second oxide semiconductor film 41 is formed by, for example, a CVD method.

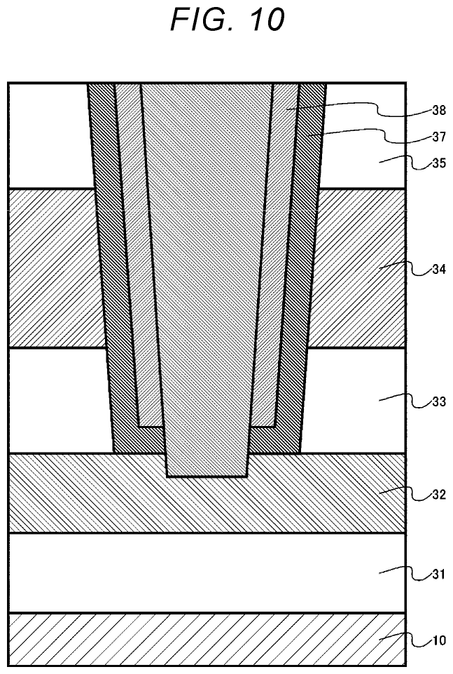

Subsequently, the upper portion of the second oxide semiconductor film 41 is removed to expose the surface of the third silicon oxide film 35 (FIG. 10). The second oxide semiconductor film 41 is removed by, for example, etching using a RIE method.

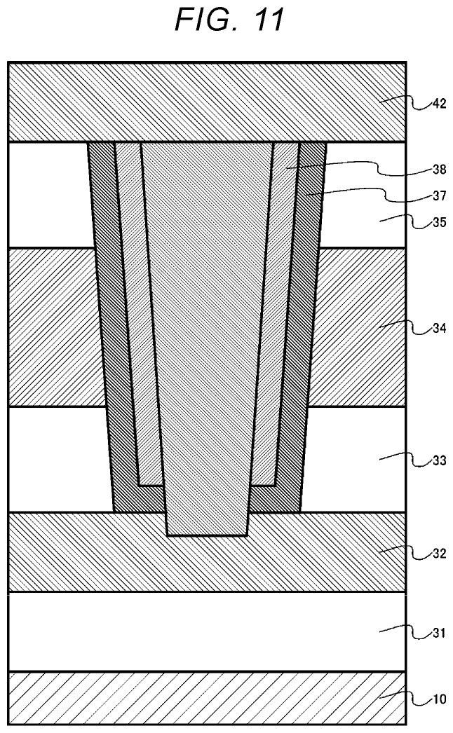

Subsequently, a second indium tin oxide film 42 is formed (FIG. 11). The second indium tin oxide film 42 is an example of a second conductive film. The second indium tin oxide film 42 is formed by, for example, a CVD method. The second indium tin oxide film 42 finally becomes the upper electrode 14.

The transistor 100 illustrated in FIGS. 1 to 3 is manufactured by the above manufacturing method.

In the following, an operation and effect of the semiconductor device according to the first embodiment will be described.

An oxide semiconductor transistor that forms a channel in an oxide semiconductor layer has an excellent characteristic that a channel leakage current during an OFF-operation is extremely small. As a result, for example, it is considered to apply an oxide semiconductor transistor to a switching transistor of a memory cell of a DRAM. Since a channel leakage current during an OFF-operation is extremely small, a charge retention property of the DRAM is improved by applying the oxide semiconductor transistor to the switching transistor.

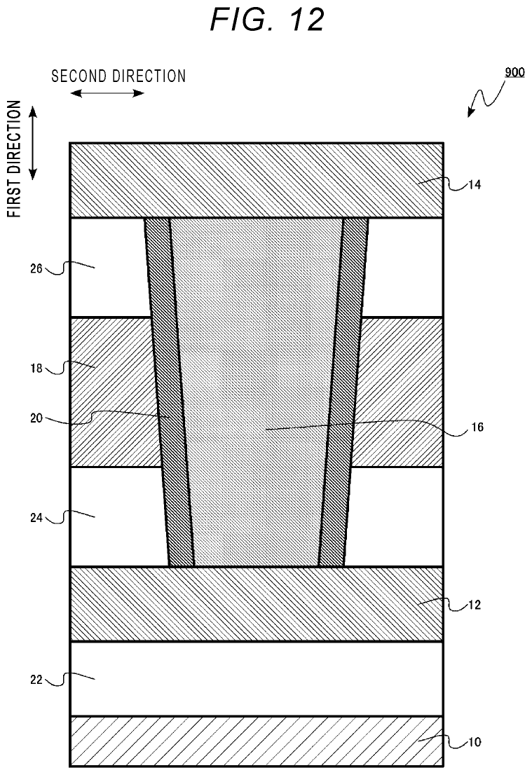

FIG. 12 is a schematic cross-sectional view of a semiconductor device according to a comparative example. FIG. 12 is a drawing corresponding to FIG. 1 of the semiconductor device according to the first embodiment.

The semiconductor device according to the comparative example is a transistor 900. The transistor 900 is an oxide semiconductor transistor. The transistor 900 is different from the transistor 100 according to the first embodiment in that the second oxide semiconductor layer 17 is not provided between the gate electrode 18 and the first oxide semiconductor layer 16. Further, the transistor 900 is different from the transistor 100 according to the first embodiment in that the first oxide semiconductor layer 16 is not provided with the first portion 16a.

In the transistor 900 according to the comparative example, the gate insulating layer 20 and the first oxide semiconductor layer 16 are in contact with each other.

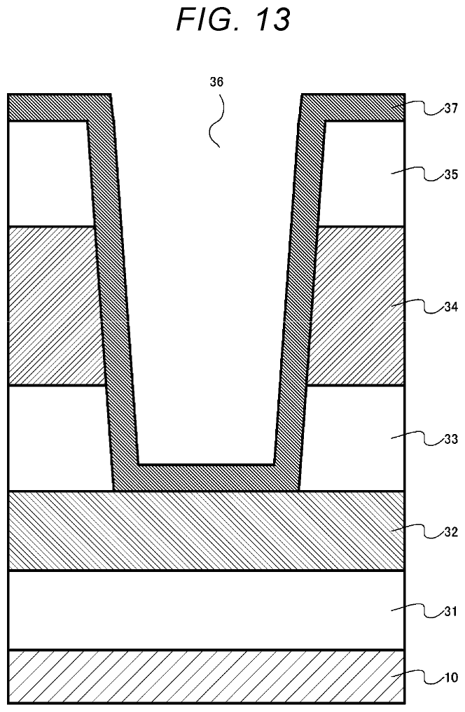

FIGS. 13 to 15 are schematic cross-sectional views illustrating the example of the method for manufacturing the semiconductor device according to the comparative example. Each of FIGS. 13 to 15 illustrates a cross section corresponding to FIG. 12. FIGS. 13 to 15 are drawings illustrating an example of a method for manufacturing the transistor 900.

It is the same as the manufacturing method according to the first embodiment until the fourth silicon oxide film 37 is formed inside the opening 36 (FIG. 13). The fourth silicon oxide film 37 is formed by, for example, a CVD method. A part of the fourth silicon oxide film 37 finally becomes the gate insulating layer 20.

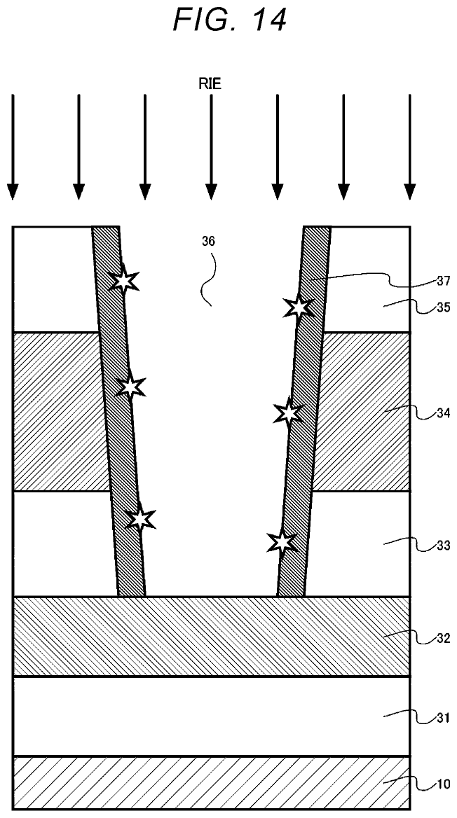

Subsequently, the fourth silicon oxide film 37 at the lower portion of the opening 36 is etched to expose the first indium tin oxide film 32 (FIG. 14). The fourth silicon oxide film 37 is etched by using a RIE method.

When the fourth silicon oxide film 37 is etched, the surface of the fourth silicon oxide film 37 is exposed to the etching, and thus, processing damage is added.

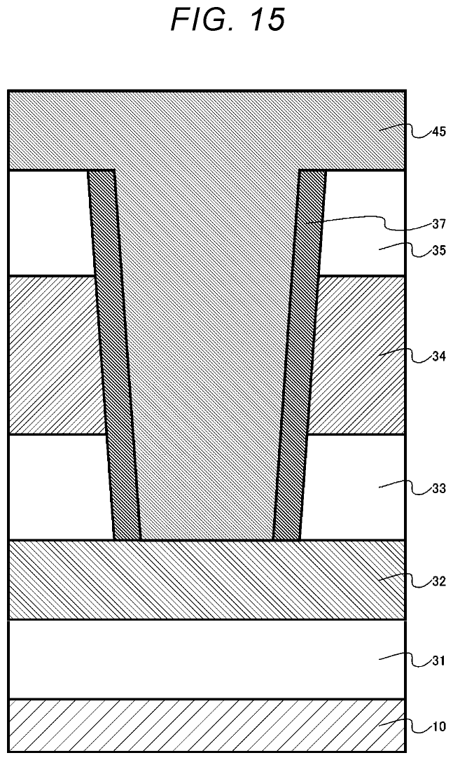

Subsequently, the opening 36 is buried with an oxide semiconductor film 45 (FIG. 15). A part of the oxide semiconductor film 45 becomes the first oxide semiconductor layer 16.

The oxide semiconductor film 45 contains, for example, indium (In), gallium (Ga), and zinc (Zn). The oxide semiconductor film 45 is formed by, for example, a CVD method.

Thereafter, the upper portion of the oxide semiconductor film 45 is removed to expose the surface of the third silicon oxide film 35. Thereafter, similarly to the manufacturing method according to the first embodiment, an indium tin oxide film, which becomes the upper electrode 14, is formed.

The transistor 900 illustrated in FIG. 12 is manufactured by the above manufacturing method.

In the method for manufacturing the transistor 900 according to the comparative example, when the fourth silicon oxide film 37 at the lower portion of the opening 36 is etched, the surface of the fourth silicon oxide film 37 that becomes the gate insulating layer 20 is exposed to the etching, and thus, processing damage is added. Particularly, when the surface of the fourth silicon oxide film 37 is a forward-taper shape, the processing damage added to the surface increases. As a result, for example, the leakage current of the gate insulating layer 20 of the transistor 900 is increased, or the reliability of the gate insulating layer 20 is lowered.

Further, for example, processing damage is added to an interface between the gate insulating layer 20 and the first oxide semiconductor layer 16, so that the mobility of the carrier is lowered, and an ON-current of the transistor 900 is lowered.

In the transistor 100 according to the first embodiment, the second oxide semiconductor layer 17 is provided between the gate insulating layer 20 and the first oxide semiconductor layer 16. By providing the second oxide semiconductor layer 17, when the fourth silicon oxide film 37 at the lower portion of the opening 36 is etched, the surface of the fourth silicon oxide film 37 that becomes the gate insulating layer 20 is protected by the first oxide semiconductor film 38.

Therefore, the surface of the fourth silicon oxide film 37 that becomes the gate insulating layer 20 is not exposed to the etching. Therefore, the leakage current of the gate insulating layer 20 of the transistor 100 is not increased, and the reliability of the gate insulating layer 20 is not lowered.

Further, in the transistor 100 according to the first embodiment, the first oxide semiconductor layer 16 is provided with the first portion 16a in contact with the lower electrode 12. By providing the first portion 16a, it is possible to increase the contact area between the first oxide semiconductor layer 16 and the lower electrode 12. Therefore, the contact resistance between the first oxide semiconductor layer 16 and the lower electrode 12 is reduced. Therefore, the ON-current of the transistor 100 is increased.

In the transistor 100 according to the first embodiment, when the fourth silicon oxide film 37 at the lower portion of the opening 36 is etched, the surface of the fourth silicon oxide film 37 that becomes the gate insulating layer 20 is protected by the first oxide semiconductor film 38. As a result, it is easy to form the recess portion 40 (FIG. 8) by over-etching. The first portion 16a in contact with the lower electrode 12 may be formed by using the recess portion 40.

From the above, according to the first embodiment, a semiconductor device having an excellent transistor characteristic is provided.

### Second Embodiment

A semiconductor device according to a second embodiment is different from the semiconductor device according to the first embodiment in that the chemical composition of the first oxide semiconductor layer and the chemical composition of the second oxide semiconductor layer are different from each other. In the following, some descriptions may be omitted for the contents that overlap with the first embodiment.

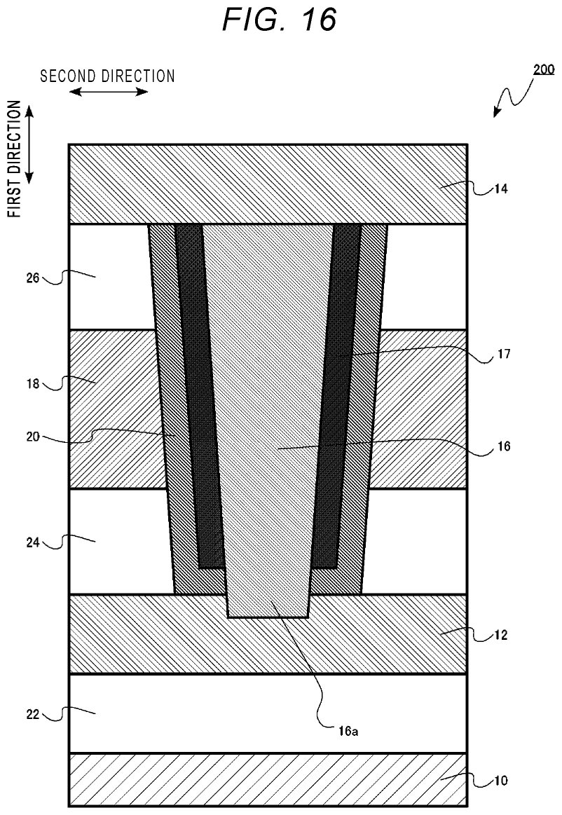

FIG. 16 is a schematic cross-sectional view of the semiconductor device according to the second embodiment. FIG. 16 is a drawing corresponding to FIG. 1 of the first embodiment.

The semiconductor device according to the second embodiment is a transistor 200. The transistor 200 is an oxide semiconductor transistor in which a channel is formed in the oxide semiconductor. In the transistor 200, a gate electrode surrounds the oxide semiconductor layer in which the channel is formed. The transistor 200 is a so-called SGT. The transistor 200 is a so-called vertical transistor.

The transistor 200 is provided with the lower electrode 12, the upper electrode 14, the first oxide semiconductor layer 16, the second oxide semiconductor layer 17, the gate electrode 18, the gate insulating layer 20, the lower insulating layer 24, and the upper insulating layer 26. The first oxide semiconductor layer 16 includes the first portion 16a.

In the transistor 200, the chemical composition of the first oxide semiconductor layer 16 and the chemical composition of the second oxide semiconductor layer 17 are different from each other.

For example, the atomic concentration of indium (In) in the second oxide semiconductor layer 17 is higher than the atomic concentration of indium (In) in the first oxide semiconductor layer 16. For example, the second oxide semiconductor layer 17 and the first oxide semiconductor layer 16 contains indium (In), gallium (Ga), and zinc (Zn), and the atomic concentration of indium (In) in the second oxide semiconductor layer 17 is higher than the atomic concentration of indium (In) in the first oxide semiconductor layer 16.

Further, for example, the atomic concentration of gallium (Ga) in the first oxide semiconductor layer 16 is higher than the atomic concentration of gallium (Ga) in the second oxide semiconductor layer 17. For example, the first oxide semiconductor layer 16 and the second oxide semiconductor layer 17 contains indium (In), gallium (Ga), and zinc (Zn), and the atomic concentration of gallium (Ga) in the first oxide semiconductor layer 16 is higher than the atomic concentration of gallium (Ga) in the second oxide semiconductor layer 17.

Further, for example, the second oxide semiconductor layer 17 contains indium (In), aluminum (Al), and zinc (Zn), and the first oxide semiconductor layer 16 contains indium (In), gallium (Ga), and zinc (Zn). For example, the atomic concentration of aluminum (Al) in the second oxide semiconductor layer 17 is higher than the atomic concentration of aluminum (Al) in the first oxide semiconductor layer 16.

According to the transistor 200 according to the second embodiment, the chemical composition of the first oxide semiconductor layer 16 and the chemical composition of the second oxide semiconductor layer 17 may be changed to optimize the transistor characteristic.

For example, the atomic concentration of indium (In) in the second oxide semiconductor layer 17 may be set to be higher than the atomic concentration of indium (In) in the first oxide semiconductor layer 16, so that the mobility of the carrier of the transistor 200 may be improved, and the ON-current may be increased.

The atomic concentration of indium (In) in the second oxide semiconductor layer 17 is set to be high, so that the mobility of the carrier of the second oxide semiconductor layer 17 is improved. In the transistor 200, the second oxide semiconductor layer 17 is separated from the lower electrode 12 with the gate insulating layer 20 interposed therebetween. Therefore, a direct current path from the second oxide semiconductor layer 17 to the lower electrode 12 is blocked. Therefore, even when the mobility of the carrier of the second oxide semiconductor layer 17 is improved, the increase in the OFF-leakage current of the transistor 200 may be prevented.

Further, the atomic concentration of gallium (Ga) in the first oxide semiconductor layer 16 may be set to be higher than the atomic concentration of gallium (Ga) in the second oxide semiconductor layer 17, so that the mobility of the carrier of the transistor 200 may be lowered, and the OFF-leakage current may be reduced.

The atomic concentration of gallium (Ga) in the first oxide semiconductor layer 16 is set to be high, so that the mobility of the carrier of the first oxide semiconductor layer 16 is lowered. In the transistor 200, the second oxide semiconductor layer 17 is provided immediately below the gate insulating layer 20. The ON-current mainly flows through the second oxide semiconductor layer 17 immediately below the gate insulating layer 20. Therefore, even when the mobility of the carrier of the first oxide semiconductor layer 16 is lowered, the lowering of the ON-current of the transistor 200 may be prevented.

Further, the atomic concentration of aluminum (Al) in the second oxide semiconductor layer 17 may be set to be higher than the atomic concentration of aluminum (Al) in the first oxide semiconductor layer 16, so that the fluctuation of the threshold voltage of the transistor 200 may be prevented. The second oxide semiconductor layer 17 contains, for example, indium (In), aluminum (Al), and zinc (Zn).

The atomic concentration of aluminum (Al) in the second oxide semiconductor layer 17 is set to be high, so that the heat resistance of the second oxide semiconductor layer 17 is improved. Therefore, the fluctuation of the threshold voltage of the transistor 200 may be prevented. The chemical composition of the first oxide semiconductor layer 16 may be selected to optimize characteristics other than the heat resistance. The first oxide semiconductor layer 16 contains, for example, indium (In), gallium (Ga), and zinc (Zn).

[Modification]

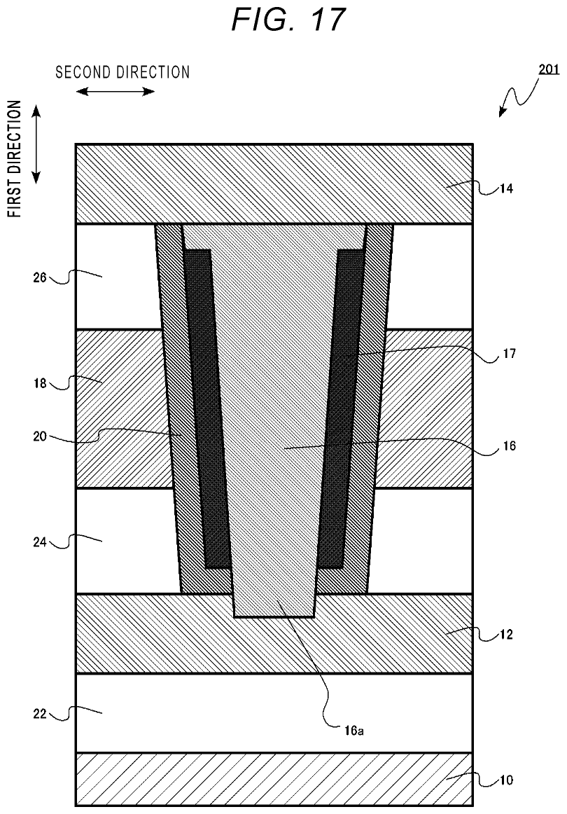

FIG. 17 is a schematic cross-sectional view of a semiconductor device according to Modification of the second embodiment. FIG. 17 is a drawing corresponding to FIG. 16 of the second embodiment.

A transistor 201 according to Modification of the second embodiment is different from the transistor 200 according to the second embodiment in that the second oxide semiconductor layer 17 is separated from the upper electrode 14. In the first direction, the first oxide semiconductor layer 16 is provided between the second oxide semiconductor layer 17 and the upper electrode 14. The transistor 201 according to Modification may be formed by, for example, when etching for forming the recess portion corresponding to FIG. 8 in the manufacturing method according to the first embodiment, selecting the etching condition in which the etching rate of the oxide semiconductor film that becomes the second oxide semiconductor layer 17 is faster than the etching rate of the oxide silicon film that becomes the gate insulating layer 20.

According to the transistor 201 according to Modification, the second oxide semiconductor layer 17 is separated from the upper electrode 14 with the first oxide semiconductor layer 16 interposed therebetween. Therefore, a direct current path from the second oxide semiconductor layer 17 to the upper electrode 14 is blocked. Therefore, even when the mobility of the carrier of the second oxide semiconductor layer 17 is improved, the increase in the OFF-leakage current of the transistor 201 may be further prevented as compared with the transistor 200 according to the second embodiment.

From the above, according to the second embodiment and Modification thereof, a semiconductor device having an excellent transistor characteristic is provided.

### Third Embodiment

A semiconductor device according to a third embodiment is different from the semiconductor device according to the first embodiment in that a core insulating layer is provided. In the following, some descriptions may be omitted for the contents that overlap with the first embodiment.

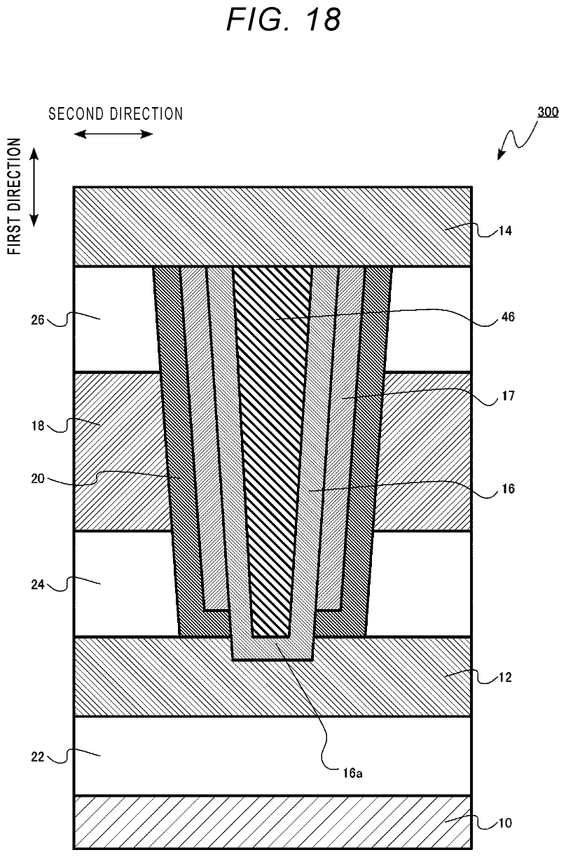

FIG. 18 is a schematic cross-sectional view of the semiconductor device according to the third embodiment. FIG. 18 is a drawing corresponding to FIG. 1 of the first embodiment.

The semiconductor device according to the third embodiment is a transistor 300. The transistor 300 is an oxide semiconductor transistor in which a channel is formed in the oxide semiconductor. In the transistor 300, a gate electrode surrounds the oxide semiconductor layer in which the channel is formed. The transistor 300 is a so-called SGT. The transistor 300 is a so-called vertical transistor.

The transistor 300 is provided with the lower electrode 12, the upper electrode 14, the first oxide semiconductor layer 16, the second oxide semiconductor layer 17, the gate electrode 18, the gate insulating layer 20, the lower insulating layer 24, and the upper insulating layer 26. The first oxide semiconductor layer 16 includes the first portion 16a and a core insulating layer 46.

The core insulating layer 46 is surrounded by the first oxide semiconductor layer 16 in the plane perpendicular to the first direction. The core insulating layer 46 includes, for example, the gate electrode 18, and is surrounded by the first oxide semiconductor layer 16 in the cross section perpendicular to the first direction.

The core insulating layer 46 is, for example, an oxide, a nitride, or an oxynitride. The core insulating layer 46 contains, for example, silicon oxide, silicon nitride, or silicon oxynitride. The core insulating layer 46 contains, for example, a silicon oxide layer, a silicon nitride layer, or a silicon oxynitride layer. The core insulating layer 46 is, for example, a silicon oxide layer, a silicon nitride layer, or a silicon oxynitride layer.

By including the core insulating layer 46, for example, the volume of the first oxide semiconductor layer 16 is lowered, and the OFF-leakage current of the transistor 300 is reduced.

From the above, according to the third embodiment, a semiconductor device having an excellent transistor characteristic is provided.

### Fourth Embodiment

A semiconductor device according to a fourth embodiment is different from the semiconductor device according to the first embodiment in that the side surface of the first oxide semiconductor layer is parallel to the first direction in the cross section parallel to the first direction. In the following, some descriptions may be omitted for the contents that overlap with the first embodiment.

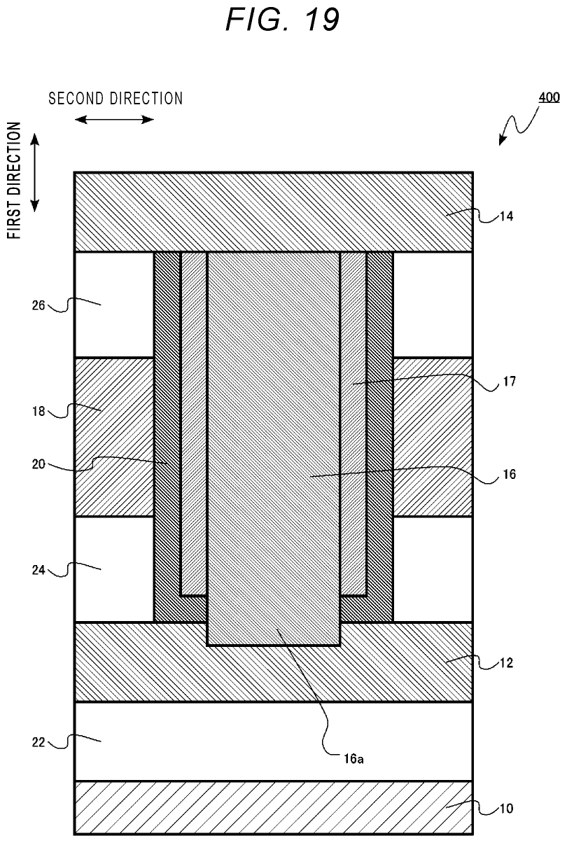

FIG. 19 is a schematic cross-sectional view of the semiconductor device according to the fourth embodiment. FIG. 19 is a drawing corresponding to FIG. 1 of the first embodiment.

The semiconductor device according to the fourth embodiment is a transistor 400. The transistor 400 is an oxide semiconductor transistor in which a channel is formed in the oxide semiconductor. In the transistor 400, a gate electrode surrounds the oxide semiconductor layer in which the channel is formed. The transistor 400 is a so-called SGT. The transistor 400 is a so-called vertical transistor.

The transistor 400 is provided with the lower electrode 12, the upper electrode 14, the first oxide semiconductor layer 16, the second oxide semiconductor layer 17, the gate electrode 18, the gate insulating layer 20, the lower insulating layer 24, and the upper insulating layer 26. The first oxide semiconductor layer 16 includes the first portion 16a.

In the cross section parallel to the first direction, the side surface of the first oxide semiconductor layer 16 is parallel to the first direction. The side surface of the first oxide semiconductor layer 16 does not have a forward-taper shape.

Since the side surface of the first oxide semiconductor layer 16 does not have a forward-taper shape, it is possible to further increase the contact area between the first portion 16a of the first oxide semiconductor layer 16 and the lower electrode 12. Therefore, the contact resistance between the first oxide semiconductor layer 16 and the lower electrode 12 is further reduced. Therefore, the ON-current of the transistor 400 is increased.

From the above, according to the fourth embodiment, a semiconductor device having an excellent transistor characteristic is provided.

### Fifth Embodiment

A semiconductor storage device according to a fifth embodiment includes: a first electrode; a second electrode; a first oxide semiconductor layer provided between the first electrode and the second electrode; a gate electrode facing the first oxide semiconductor layer; a second oxide semiconductor layer provided between the gate electrode and the first oxide semiconductor layer, and separated from the first electrode; a gate insulating layer provided between the gate electrode and the second oxide semiconductor layer, and a capacitor electrically connected to the first electrode or the second electrode.

The semiconductor storage device according to the fifth embodiment is a semiconductor memory 500. The semiconductor storage device according to the fifth embodiment is a DRAM. The semiconductor memory 500 uses the transistor 100 according to the first embodiment as a switching transistor of a memory cell of the DRAM.

In the following, some descriptions will be omitted for the contents that overlap with the first embodiment.

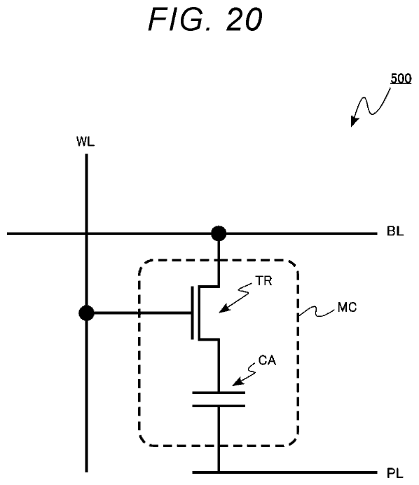

FIG. 20 is an equivalent circuit diagram of the semiconductor storage device according to the fifth embodiment. FIG. 20 illustrates a case where there is one memory cell MC. However, a plurality of memory cells MC may be provided, for example, in an array shape.

The semiconductor memory 500 is provided with a memory cell MC, a word line WL, a bit line BL, and a plate line PL. The memory cell MC includes a switching transistor TR and a capacitor CA. In FIG. 20, a region surrounded by the broken line is the memory cell MC.

The word line WL is electrically connected to a gate electrode of the switching transistor TR. The bit line BL is electrically connected to a source/drain electrode of the switching transistor TR. One electrode of the capacitor CA is electrically connected to the other side of the source/drain electrode of the switching transistor TR. The other electrode of the capacitor CA is connected to the plate line PL.

The memory cell MC stores data by storing charges in the capacitor CA. Writing and reading of the data is performed by turning on the switching transistor TR.

For example, the switching transistor TR is turned on in a state where a desired voltage is applied to the bit line BL, and data is written to the memory cell MC.

Further, for example, the switching transistor TR is turned on, the change in voltage of the bit line BL in accordance with the amount of charge stored in the capacitor is detected, and the data of the memory cell MC is read.

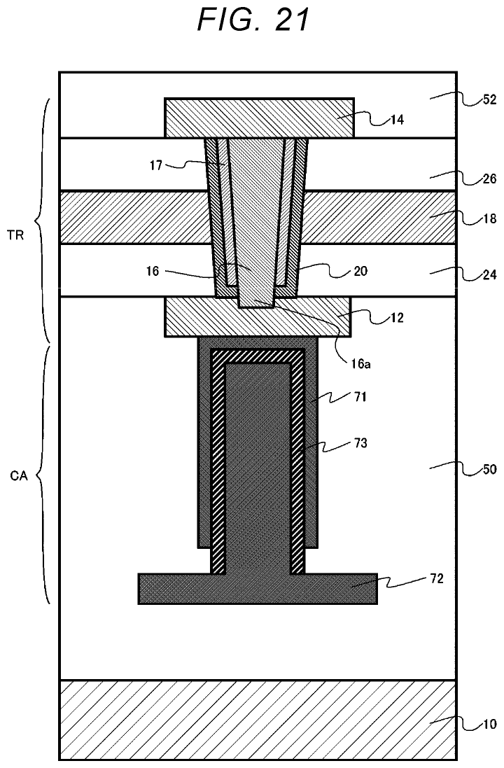

FIG. 21 is a schematic cross-sectional view of the semiconductor storage device according to the fifth embodiment. FIG. 21 illustrates a cross section of the memory cell MC of the semiconductor memory 500.

The semiconductor memory 500 includes the silicon substrate 10, the switching transistor TR, the capacitor CA, a lower interlayer insulating layer 50, and an upper interlayer insulating layer 52.

The switching transistor TR is provided with the lower electrode 12, the upper electrode 14, the first oxide semiconductor layer 16, the second oxide semiconductor layer 17, the gate electrode 18, the gate insulating layer 20, the lower insulating layer 24, and the upper insulating layer 26. The first oxide semiconductor layer 16 includes the first portion 16a.

The lower electrode 12 is an example of a first electrode. The upper electrode 14 is an example of a second electrode.

The switching transistor TR has the same structure as the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA is provided with a cell electrode 71, a plate electrode 72, and a capacitor insulating film 73. The cell electrode 71 is electrically connected to the lower electrode 12. The cell electrode 71 is, for example, in contact with the lower electrode 12.

The cell electrode 71 and the plate electrode 72 are, for example, titanium nitride. The capacitor insulating film 73 has, for example, a stacked structure of zirconium oxide, aluminum oxide, and zirconium oxide.

The gate electrode 18 is, for example, electrically connected to the word line WL (not illustrated). The upper electrode 14 is, for example, electrically connected to the bit line BL (not illustrated). The plate electrode 72 is, for example, connected to the plate line PL (not illustrated).

The semiconductor memory 500 applies the oxide semiconductor transistor having an extremely small channel leakage current when turned off to the switching transistor TR. Therefore, a DRAM having an excellent charge retention property is provided.

Further, in the switching transistor TR of the semiconductor memory 500, for example, the leakage current of the gate insulating layer 20 is reduced. Therefore, the operation characteristics of the semiconductor memory 500 are improved.

In the first to the fourth embodiments, the transistor in which the gate electrode 18 surrounds the first oxide semiconductor layer 16 is described as an example. However, the transistor according to the embodiments of the present disclosure may be a transistor in which the gate electrode does not surround the oxide semiconductor layer. For example, the transistor according to the embodiments of the present disclosure may be a transistor in which the oxide semiconductor layer is embedded between two gate electrodes.

In the fifth embodiment, the semiconductor memory to which the transistor according to the first embodiment is applied is described as an example. However, the semiconductor memory according to the embodiments of the present disclosure may be a semiconductor memory to which the transistors according to the second to the fourth embodiment are applied.

In the fifth embodiment, the semiconductor memory in which the cell electrode is electrically connected to the lower electrode 12 is described as an example. However, the semiconductor memory according to the embodiments of the present disclosure may be a semiconductor memory in which the cell electrode is electrically connected to the upper electrode 14.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. For example, an element of an embodiment may be replaced by an element of another embodiment or may be changed. The accompanying claims and their equivalents are intended to cover such forms or modifications as would fall within the scope and spirit of the disclosure.

What is claimed is:

1. A semiconductor device comprising:
a first electrode;
a second electrode;
a first oxide semiconductor layer provided between the first electrode and the second electrode;
a gate electrode around the first oxide semiconductor layer;
a second oxide semiconductor layer provided between the gate electrode and the first oxide semiconductor layer, and separated from the first electrode; and
a gate insulating layer provided between the gate electrode and the second oxide semiconductor layer.

2. The semiconductor device according to claim 1, wherein the first oxide semiconductor layer is in contact with the first electrode and the second electrode.

3. The semiconductor device according to claim 1, wherein the gate insulating layer further includes a portion provided between the second oxide semiconductor layer and the first electrode.

4. The semiconductor device according to claim 1, wherein the first oxide semiconductor layer includes a first portion surrounded by the first electrode.

5. The semiconductor device according to claim 1, wherein the gate electrode surrounds the first oxide semiconductor layer.

6. The semiconductor device according to claim 1, wherein a chemical composition of the first oxide semiconductor layer and a chemical composition of the second oxide semiconductor layer are different from each other.

7. The semiconductor device according to claim 6, wherein an atomic concentration of indium (In) of the second oxide semiconductor layer is higher than an atomic concentration of indium (In) of the first oxide semiconductor layer.

8. The semiconductor device according to claim 6, wherein an atomic concentration of gallium (Ga) of the first oxide semiconductor layer is higher than an atomic concentration of gallium (Ga) of the second oxide semiconductor layer.

9. The semiconductor device according to claim 1, wherein the second oxide semiconductor layer is further separated from the second electrode.

10. The semiconductor device according to claim 9, wherein the first oxide semiconductor layer is provided between the second oxide semiconductor layer and the second electrode.

11. A semiconductor storage device comprising:
a first electrode;
a second electrode;
a first oxide semiconductor layer extending between the first electrode and the second electrode;
a gate electrode around the first oxide semiconductor layer;
a second oxide semiconductor layer provided between the gate electrode and the first oxide semiconductor layer, and separated from the first electrode;
a gate insulating layer provided between the gate electrode and the second oxide semiconductor layer; and
a capacitor electrically connected to one of the first electrode or the second electrode.

12. The semiconductor storage device according to claim 11, wherein the first oxide semiconductor layer is in contact with the first electrode and the second electrode.

13. The semiconductor storage device according to claim 11, wherein the gate insulating layer is provided between the second oxide semiconductor layer and the first electrode.

14. The semiconductor storage device according to claim 11, wherein the first oxide semiconductor layer includes a first portion surrounded by the first electrode.

15. The semiconductor storage device according to claim 11, wherein the gate electrode surrounds the first oxide semiconductor layer.

16. The semiconductor storage device according to claim 11, wherein a chemical composition of the first oxide semiconductor layer and a chemical composition of the second oxide semiconductor layer are different from each other.

17. The semiconductor storage device according to claim 16, wherein an atomic concentration of indium (In) of the second oxide semiconductor layer is higher than an atomic concentration of indium (In) of the first oxide semiconductor layer.

18. The semiconductor storage device according to claim 16, wherein an atomic concentration of gallium (Ga) of the first oxide semiconductor layer is higher than an atomic concentration of gallium (Ga) of the second oxide semiconductor layer.

19. The semiconductor storage device according to claim 11, wherein the second oxide semiconductor layer is further separated from the second electrode.

20. The semiconductor storage device according to claim 19, wherein the first oxide semiconductor layer is provided between the second oxide semiconductor layer and the second electrode.
